(19) United States
(12) Patent Application Publication
(10) Pub. No.: US 2017/0250714 A1
(43) Pub. Date: Aug. 31, 2017

(54) ERROR CORRECTION CIRCUIT AND ERROR CORRECTION METHOD

(71) Applicant: SK hynix Inc., Gyeonggi-do (KR)

(72) Inventor: Kyung Bum KIM, Gyeonggi-do (KR)

(21) Appl. No.: 15/219,409

(22) Filed: Jul. 26, 2016

(30) Foreign Application Priority Data
Feb. 26, 2016 (KR) 10-2016-0023622

(51) Int. Cl. H03M 13/29; H03M 13/00; H03M 13/15; G06F 11/10

(52) U.S. Cl. CPC H03M 13/2951; G06F 11/1076; H03M 13/616; H03M 13/1575

(57) ABSTRACT

An error correction method includes performing a first error correction operation, the first error correction operation including performing a syndrome check operation by calculating a syndrome matrix corresponding to a codeword based on a parity check matrix, performing a decoding operation for the codeword according to a result of the syndrome check operation, and iterating the decoding operation until the syndrome check operation is passed for a codeword acquired as the decoding operation is performed or an iteration count of the decoding operation reaches a threshold count; accumulating syndrome matrixes, which are calculated as the decoding operation is iterated, to an accumulation matrix; and performing a second error correction operation for a last codeword acquired through the iterating of the decoding operation for the codeword, based on the accumulation matrix, when the iteration count reaches the threshold count.

### CROSS-REFERENCES TO RELATED APPLICATION

The present application claims priority under 35 U.S.C. §119(a) to Korean application number 10-2016-0023622, filed on Feb. 26, 2016, which is herein incorporated by reference in its entirety.

### BACKGROUND

1. Technical Field

Various embodiments generally relate to an error correction circuit, and more particularly to an error correction circuit which utilizes an iterative decoding technique.

2. Related Art

Data storage devices store data provided by an external device in response to a write request. Data storage devices may also provide stored data to an external device in response to a read request. Examples of external devices that use data storage devices include computers, digital cameras, cellular phones and the like. Data storage devices can be embedded in external devices or fabricated separately and then connected afterwards.

A data storage device may include an error correction circuit to correct error bits occurred in stored data.

### SUMMARY

In an embodiment, an error correction method may include: performing a first error correction operation, the first error correction operation including performing a syndrome check operation by calculating a syndrome matrix corresponding to a codeword based on a parity check matrix, performing a decoding operation for the codeword according to a result of the syndrome check operation, and iterating the decoding operation until the syndrome check operation passed for a codeword acquired as the decoding operation is performed or an iteration count of the decoding operation reaches a threshold count; accumulating syndrome matrixes, which are calculated as the decoding operation is iterated, to an accumulation matrix; and performing a second error correction operation for a last codeword acquired through the iterating of the decoding operation for the codeword, based on the accumulation matrix, when the iteration count reaches the threshold count.

In an embodiment, an error correction method may include: calculating syndrome values for respective bit groups of a codeword based on a parity check matrix, while a decoding operation is iterated to a threshold count; counting dissatisfaction counts as counts in which the respective bit groups have not satisfied a syndrome check, based on the syndrome values; selecting a predetermined number of bit groups among bit groups of a last codeword acquired through the decoding operation, based on the dissatisfaction counts of the bit groups; selecting one or more bits which are included in common in all of the selected bit groups; selectively bit-flipping the selected bits; and performing a syndrome check operation for a bit-flipped codeword.

In an embodiment, acquiring codewords while a decoding operation is iterated to a threshold count according to a result of a syndrome check operation, the syndrome check operation including calculating syndrome matrixes respectively corresponding to the codewords; accumulating the syndrome matrixes to an accumulation matrix; and performing a bit-flip operation for a last codeword among the codewords, based on the accumulation matrix.

In an embodiment, an error correction circuit may include: a syndrome check unit configured to perform a syndrome check operation by calculating a syndrome matrix corresponding to a codeword, based on a parity check matrix; a decoder configured to perform a decoding operation for the codeword according to a result of the syndrome check operation, and iterate the decoding operation until the syndrome check operation is passed for a codeword acquired as the decoding operation is performed or an iteration count of the decoding operation reaches a threshold count; an accumulation unit configured to accumulate syndrome matrixes calculated from the syndrome check unit as the decoding operation is iterated, to an accumulation matrix; and a bit flip unit configured to perform a bit-flip operation for a last codeword acquired through the decoding operation for the codeword, based on the accumulation matrix, when the iteration count reaches the threshold count.

In an embodiment, the bit flip unit selects a predetermined number of accumulation values in the accumulation matrix, selects one or more bits in the last codeword based on the selected accumulation values, and selectively bit-flips the selected bits, and the syndrome check unit performs the syndrome check operation for a bit-flipped codeword.

In an embodiment, the bit flip unit selects the predetermined number of accumulation values by arranging accumulation values of the accumulation matrix in a descending order.

In an embodiment, the bit flip unit selects the predetermined number of accumulation values by arranging partial accumulation values of the accumulation matrix in a descending order, and the respective partial accumulation values have corresponding syndrome values in a last syndrome matrix corresponding to the last codeword that do not satisfy a syndrome check.

In an embodiment, the bit flip unit selects one or more rows corresponding to the selected accumulation values among rows of the parity check matrix, searches one or more positions in which a predetermined value is positioned in common in the selected rows, and selects one or more bits corresponding to the searched positions, in the last codeword.

In an embodiment, the bit flip unit selects bit groups respectively corresponding to the selected accumulation values among bit groups of the last codeword, and selects one or more bits which are included in all the selected bit groups.

In an embodiment, the bit flip unit iterates bit-flipping for sub sets of the selected bits until the syndrome check operation is passed for the bit-flipped codeword.

### BRIEF DESCRIPTION OF THE DRAWINGS

FIG. 1 is a block diagram illustrating an error correction circuit in accordance with an embodiment.

FIG. 2 is a diagram illustrating the syndrome check operation of the syndrome check unit and the operation of the accumulation unit shown in FIG. 1.

FIG. 3 is a diagram illustrating the operation of the bit flip unit shown in FIG. 1.

FIG. 4 is a diagram illustrating the operation of the bit flip unit shown in FIG. 1.

FIG. 5 is a diagram illustrating the operation of the bit flip unit shown in FIG. 1.

FIG. 6 is a flow chart illustrating a method for operating the error correction circuit of FIG. 1.

FIG. 7 is a flow chart illustrating a method for the error correction circuit of FIG. 1 to perform a second error correction operation.

FIG. 8 is a flow chart illustrating a method for the error correction circuit of FIG. 1 to perform a second error correction operation.

FIG. 9 is a block diagram illustrating a data storage device to which the error correction circuit in accordance with the embodiment is applied.

FIG. 10 is a block diagram illustrating a data processing system to which the data storage device of FIG. 9 is applied.

### DETAILED DESCRIPTION

Hereinafter, a data storage device and an operating method thereof according to the present invention will be described with reference to the accompanying drawings through exemplary embodiments of the present invention. The present invention may, however, be embodied in different forms and should not be construed as being limited to the embodiments set forth herein. Rather, these embodiments are provided to describe the present invention in detail to the extent that a person skilled in the art to which the invention pertains can enforce the technical concepts of the present invention.

It is to be understood that embodiments of the present invention are not limited to the particulars shown in the drawings, that the drawings are not necessarily to scale, and, in some instances, proportions may have been exaggerated in order to more clearly depict certain features of the invention. While particular terminology is used, it is to be appreciated that the terminology used is for describing particular embodiments only and is not intended to limit the scope of the present invention.

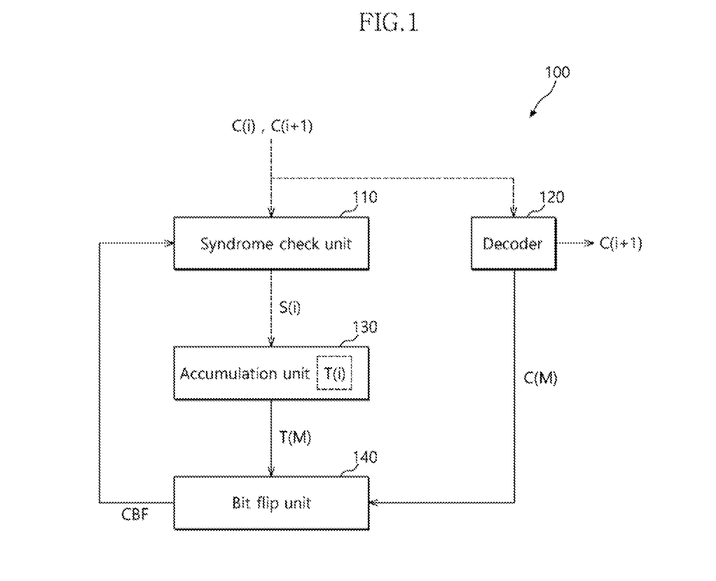

FIG. 1 is a block diagram illustrating an error correction circuit 100 in accordance with an embodiment.

The error correction circuit 100 may perform a first error correction operation and a second error correction operation. The error correction circuit 100 may perform the second error correction operation when all error bits are not corrected through the first error correction operation. In FIG. 1, the transmission of information indicated by the dotted lines may be associated with the first error correction operation, and the transmission of information indicated by the solid lines may be associated with the second error correction operation.

In detail, the error correction circuit 100 may perform the first error correction operation by iterating a decoding operation to a threshold count M according to a result of a syndrome check operation. The error correction circuit 100 may accumulate a syndrome matrix S(i) calculated each time the decoding operation is iterated in the first error correction operation, to an accumulation matrix T(i). The error correction circuit 100 may perform the second error correction operation by selectively bit-flipping bits having a high probability to be error bits, from a last codeword C(M) generated last when the iteration count of the first error correction operation reaches the threshold count M, based on an accumulation matrix T(M).

The error correction circuit 100 may include a syndrome check unit 110, a decoder 120, an accumulation unit 130, and a bit flip unit 140.

The syndrome check unit 110 may perform the syndrome check operation by calculating a syndrome matrix S(i) corresponding to a codeword C(i), based on a parity check matrix. The syndrome check unit 110 may perform the syndrome check operation to determine whether the codeword C(i) includes an error bit.

The decoder 120 may perform the decoding operation for the codeword C(i) according to a result of the syndrome check operation of the syndrome check unit 110. A codeword C(i+1) acquired as the decoding operation is performed for the codeword C(i) may be inputted to the syndrome check unit 110, and the syndrome check operation may be performed again by the syndrome check unit 110. The decoder 120 may iterate the decoding operation for the codeword C(i+1), according to a result of the syndrome check operation for the codeword C(i+1), that is, whether the codeword C(i+1) includes an error bit. The decoder 120 may iterate the decoding operation until the syndrome check operation is passed for a codeword acquired as the decoding operation is performed. Furthermore, the decoder 120 may iterate the decoding operation until the iteration count of the decoding operation reaches the threshold count M.

The accumulation unit 130 may accumulate syndrome matrixes S(i) calculated from the syndrome check unit 110 as the decoding operation is iterated, to the accumulation matrix T(i).

The process described thus far, in which the syndrome check operation of the syndrome check unit 110 and the decoding operation of the decoder 120 are iterated, may be included in the first error correction operation. If the syndrome check operation is not passed until the iteration count of the decoding operation reaches the threshold count M, the first error correction operation may end and the second error correction operation which will be described below may start.

First, the accumulation unit 130 may transmit the accumulation matrix T(M) to the bit flip unit 140. The accumulation matrix T(M) may be a matrix in which syndrome matrixes S(i) are accumulated until the iteration count of the decoding operation reaches the threshold count M.

The bit flip unit 140 may perform a bit flip operation for the last codeword C(M) acquired through the decoding operation when the iteration count of the decoding operation reaches the threshold count M, based on the accumulation matrix T(M). The bit flip unit 140 may generate a bit-flipped codeword CBF through the bit flip operation for the last codeword C(M). The bit flip unit 140 may transmit the bit-flipped codeword CBF to the syndrome check unit 110. The bit flip unit 140 may iterate the bit flip operation by selectively bit-flipping the bits of the last codeword C(M) until the syndrome check operation is passed for the bit-flipped codeword CBF.

In detail, the bit flip unit 140 may select a predetermined number of accumulation values from the accumulation matrix T(M). The bit flip unit 140 may mark or select one or more bits in the last codeword C(M), based on the selected accumulation values. The bit flip unit 140 may generate the bit-flipped codeword CBF by selectively bit-flipping the marked bits. The bit flip unit 140 may iterate bit-flipping for sub sets of the marked bits until the syndrome check operation of the syndrome check unit 110 is passed for the bit-flipped codeword CBF.

A method for the bit flip unit 140 to select accumulation values from the accumulation matrix T(M) is as follows. For example, the bit flip unit 140 may select a predetermined number of accumulation values by arranging the accumulation values of the accumulation matrix T(M) in a descending order. According to an embodiment, the bit flip unit 140 may select a predetermined number of accumulation values by arranging partial accumulation values of the accumulation matrix T(M) in descending order, and the respective partial accumulation values may be ones of which corresponding syndrome values in a last syndrome matrix corresponding to the last codeword C(M) do not satisfy syndrome check.

A method for the bit flip unit 140 to mark one or more bits in the last codeword C(M) based on the selected accumulation values is as follows. The bit flip unit 140 may select one or more rows corresponding to the selected accumulation values among the rows of the parity check matrix. The bit flip unit 140 may search one or more positions where a predetermined value “1” is positioned in common in the selected rows. The bit flip unit 140 may mark one or more bits corresponding to the searched positions in the last codeword C(M).

According to an embodiment, the bit flip unit 140 may select 25 bit groups respectively corresponding to the selected accumulation values among the bit groups of the last codeword C(M), and may mark one or more bits which are included in common in all of the selected bit groups. The bit groups of the last codeword C(M) may respectively correspond to the syndrome values of the last syndrome matrix corresponding to the last codeword C(M).

According to an embodiment, the decoder 120 may perform the decoding operation for the bit-flipped codeword CBF, according to a result of the syndrome check operation for the bit-flipped codeword CBF. The decoder 120 may iterate the decoding operation for the bit-flipped codeword CBF, to a predetermined count, in the same manner as the case of performing the first error correction operation.

The syndrome check unit 110 and the decoder 120 may operate based on an error correction algorithm of an iterative decoding scheme. For example, the syndrome check unit 110 and the decoder 120 may operate based on a low density parity check (LDPC) algorithm. However, it is to be noted that the embodiment is not limited to such.

Summarizing these, the error correction circuit 100 may provide improved error correction capability by marking bits having a high possibility to be error bits in the last codeword C(M), through the accumulation matrix T(M) of the syndrome matrixes S(i) generated in the iterative decoding operation, and by selectively bit-flipping the marked bits.

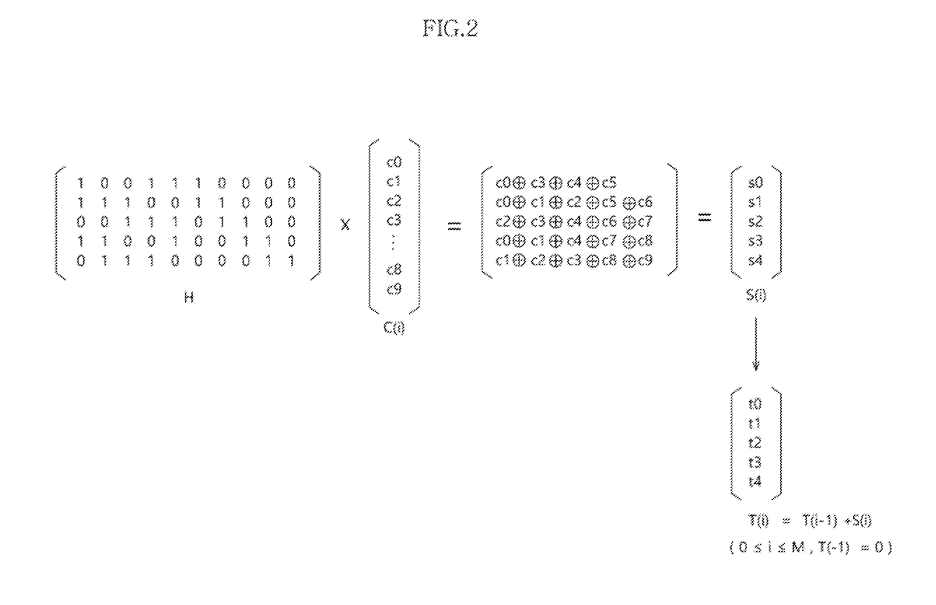

FIG. 2 is a diagram illustrating the syndrome check operation of the syndrome check unit 110 shown in FIG. 1 and the operation of the accumulation unit 130 shown in FIG. 1.

The syndrome check unit 110 may perform the syndrome check operation by calculating a syndrome matrix S(i) corresponding to a codeword C(i), based on a parity check matrix H.

In detail, the syndrome check unit 110 may calculate the syndrome matrix S(i) by multiplying the parity check matrix H and the column vector of the codeword C(i). The rows of the parity check matrix H may define the respective bit groups of the codeword C(i), and the bit groups may respectively correspond to syndrome values s0 to s4 of the syndrome matrix S(i). That is, the respective rows of the parity check matrix H may be used such that syndrome values corresponding to the respective bit groups in the codeword C(i) are generated. For example, the first row of the parity check matrix H may define a first bit group that is configured by first, fourth, fifth and sixth bits c0, c3, c4 and c5 of the codeword C(i), and may be used such that the first syndrome value s0 as a syndrome value for the first bit group is generated.

When the codeword C(i) does not include an error bit, the syndrome matrix S(i) may be calculated as a “0” matrix. However, when the codeword C(i) includes an error bit, the syndrome matrix S(i) may not be a “0” matrix. Therefore, the decoder 120 may iterate the decoding operation until the syndrome check operation for the codeword C(i) is passed, that is, the syndrome matrix S(i) corresponding to the codeword C(i) becomes “0.” However, the decoder 120 may not infinitely iterate the decoding operation, and may iterate the decoding operation until the iteration count of the decoding operation reaches the threshold count M.

While the decoding operation is iterated to the threshold count M in the first error correction operation, “M” number of codewords C(i) may be generated from the decoder 120, and “M” number of syndrome matrixes corresponding to the generated “M” number of codewords C(i) may be calculated as well. The “M” number of syndrome matrixes may be accumulated to the accumulation matrix T(i).

Summarizing these, accumulation values t0 to t4 of the accumulation matrix T(i) may be counts by which the bit groups of the codewords C(i) do not satisfy a syndrome check while the decoding operation is iterated to the threshold count M. Therefore, since the accumulation values of the last accumulation matrix T(M) are large, corresponding bit groups may have a high possibility to be related to error bits.

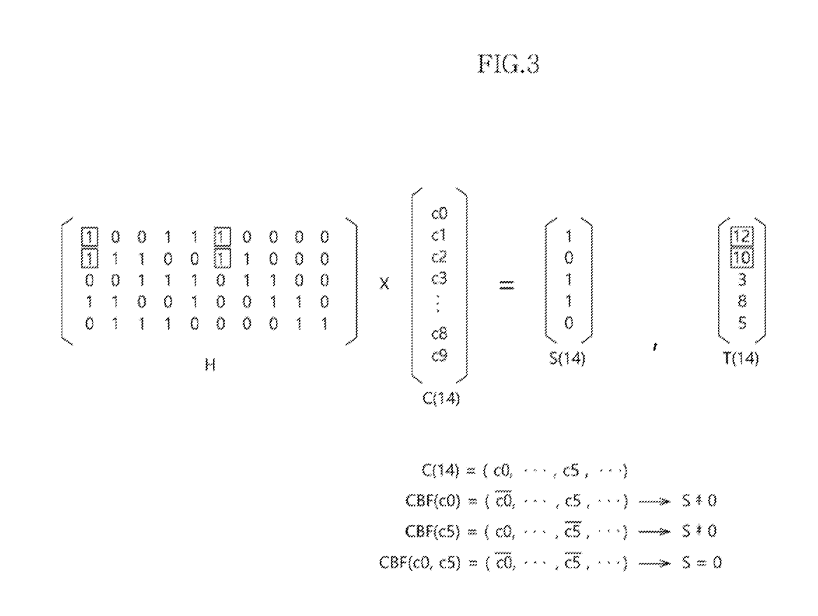

FIG. 3 is a diagram illustrating the operation of the bit flip unit 140 shown in FIG. 1. In the following descriptions, the threshold iteration count M of the decoding operation in the first error correction operation is “15” however the threshold iteration count M is not limited to “15” and can have other values.

Referring to FIG. 3, there are shown a last codeword C(14) acquired by the decoder 120, a last syndrome matrix S(14) which corresponds to the last codeword C(14) and for which the syndrome check operation is not passed, that is, which is not a “0” matrix, and an accumulation matrix T(14) to which syndrome matrixes to the last syndrome matrix S(14) are accumulated.

First, the bit flip unit 140 may select a predetermined number of accumulation values by arranging the accumulation values of the accumulation matrix T(14) in a descending order. For example, the bit flip unit 140 may select the 2 largest accumulation values that is, “12” and “10” among the 5 accumulation values included in the accumulation matrix T(14).

The bit flip unit 140 may mark bits having a high possibility to be error bits in the last codeword C(14) based on the selected accumulation values. In detail, the bit flip unit 140 may select first and second rows corresponding to the selected accumulation values among the rows of the parity check matrix H.

In this regard, first and second bit groups corresponding to the selected first and second rows may have a high possibility to be related to error bits. Therefore, bits included in common in the first and second bit groups may have a higher possibility to be error bits.

To find the bits which have a high possibility to be error bits, the bit flip unit 140 may search positions where “1” is positioned in common in the first and second rows of the parity check matrix H. The bit flip unit 140 may mark first and sixth bits c0 and c5 corresponding to searched positions, that is, first and sixth positions in the last codeword C(14).

The bit flip unit 140 may generate a bit-flipped codeword CBF by selectively bit-flipping the marked bits c0 and c5. The bit flip unit 140 may iterate bit-flipping for sub sets {c0}, {c5} and {c0, c5} of the marked bits c0 and c5 until the syndrome check operation is passed for the bit-flipped codeword CBF. In FIG. 3, since a syndrome matrix S for a codeword CBF(c0, c5) in which both the marked bits c0 and c5 are bit-flipped is calculated as a “0” matrix, the syndrome check operation may be passed.

Summarizing these, the error correction circuit 100 may efficiently correct error bits which are not corrected in the first error correction operation, through the second error correction operation based on the accumulation matrix T(M).

According to an embodiment, a predetermined number by which the bit flip unit 140 selects accumulation values from the accumulation matrix T(M), may be “1.” That is, the bit flip unit 140 may select only a maximum accumulation value from the accumulation matrix T(M). In this case, the bit flip unit 140 may perform the second error correction operation by selectively bit-flipping bits of a bit group corresponding to the selected maximum accumulation value in the last codeword C(M). For example, in FIG. 3, the bit flip unit 140 may iterate bit-flipping for “2⁴−1” number of sub sets of first, fourth, fifth and sixth bits c0, c3, c4 and c5 corresponding to the maximum accumulation value “12,” in the last codeword C(14).

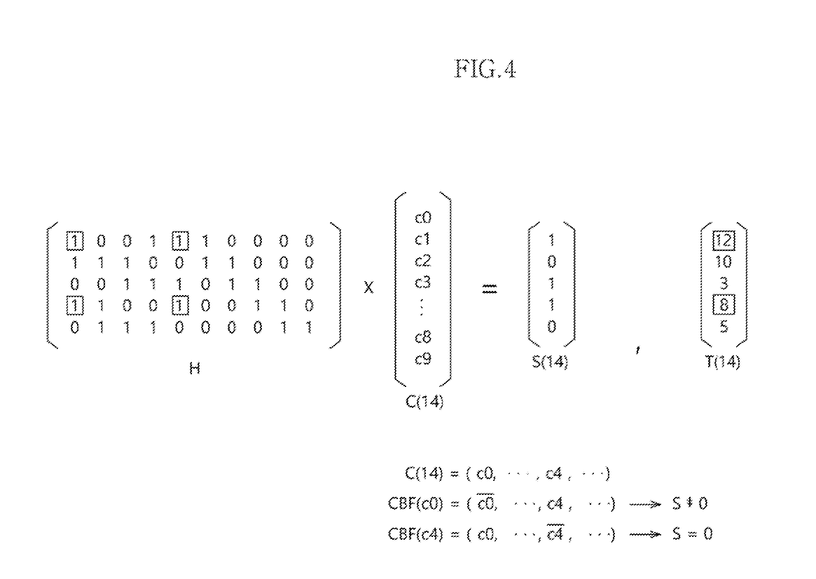

FIG. 4 is a diagram illustrating the operation of the bit flip unit 140 shown in FIG. 1.

According to an embodiment, the bit flip unit 140 may operate differently from FIG. 3 in a method of selecting a predetermined number of accumulation values in the accumulation matrix T(14). The bit flip unit 140 may determine that bit groups which have not satisfied a syndrome check immediately before the second error correction operation is started may be further related to error bits.

Referring to FIG. 4, the bit flip unit 140 may select a predetermined number of accumulation values by arranging partial accumulation values of the accumulation matrix T(14) in a descending order. For example, the bit flip unit 140 may select 2 largest accumulation values (such as, “12” and “8”) among 3 partial accumulation values (such as, “12”, “3” and “8”) included in the accumulation matrix T(14). Each of the partial accumulation values “12”, “3” and “8” may have a corresponding syndrome value (such as, “1”) that does not satisfy a syndrome check in the last syndrome matrix S(14).

The bit flip unit 140 may selectively bit-flip bits having a high possibility to be error bits in the last codeword C(14) based on the selected accumulation values. That is, the bit flip unit 140 may selectively bit-flip first and fifth bits c0 and c4 in the last codeword C(14) based on the selected accumulation values “12” and “8”. Since an operating method for this is substantially similar to the operating method described above with reference to FIG. 3, detailed descriptions thereof will be omitted herein.

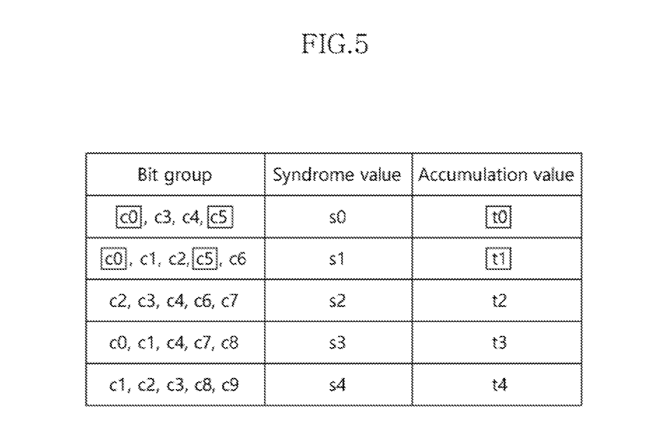

FIG. 5 is a diagram illustrating the operation of the bit flip unit 140 shown in FIG. 1.

Unlike the methods described above with reference to FIGS. 3 and 4, according to an embodiment, the bit flip unit 140 may memorize information on bit groups respectively (for example, bits included in the respective bit groups) corresponding to the rows of the parity check matrix H. In this case, the bit flip operation may be performed by a method simpler than the methods described above with reference to FIGS. 3 and 4.

In the case when first and second accumulation values t0 and t1 are selected in the accumulation matrix T(M), the bit flip unit 140 may select first and second bit groups corresponding to the accumulation values t0 and t1, and may immediately mark bits c0 and c5 which are included in common in the first and second bit groups. The bit flip unit 140 may perform the bit flip operation for the marked bits c0 and c5, in the last codeword C(M).

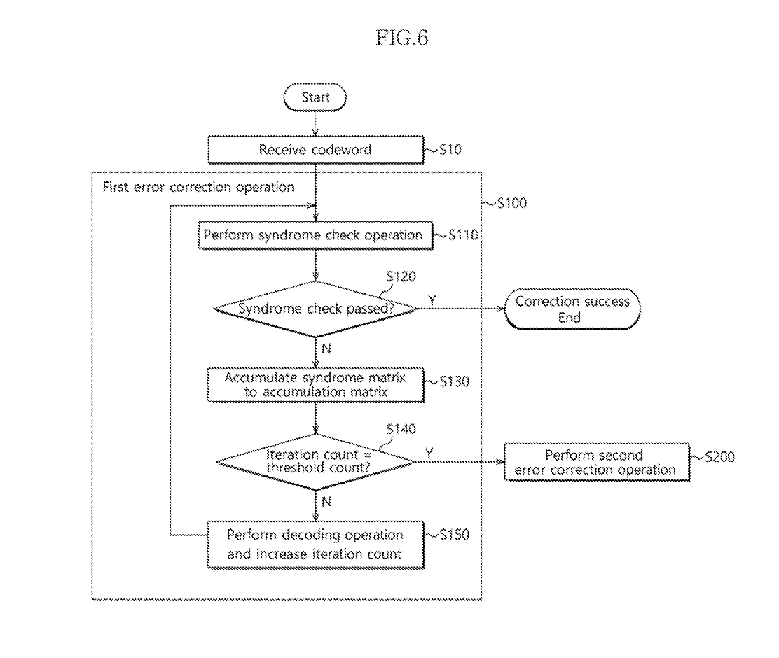

FIG. 6 is a flow chart illustrating a method for operating the error correction circuit 100 of FIG. 1.

At step S10, the error correction circuit 100 may receive an initial codeword.

At step S100, the error correction circuit 100 may perform a first error correction operation for the codeword. The step S100 may include steps S110 to S150.

At the step S110, the syndrome check unit 110 may perform a syndrome check operation by calculating a syndrome matrix corresponding to the codeword, based on a parity check matrix.

At the step S120, the syndrome check unit 110 may determine whether the codeword has passed the syndrome check operation, based on the syndrome matrix. When the syndrome matrix is “0,” the syndrome check unit 110 may determine that the codeword has passed the syndrome check operation, and the process may be ended as a correction success. When the syndrome matrix is not “0,” the syndrome check unit 110 may determine that the codeword has not passed the syndrome check operation, and the process may proceed to the step S130.

At the step S130, the accumulation unit 130 may accumulate the syndrome matrix to an accumulation matrix. An initial accumulation matrix may be a “0” matrix.

At the step S140, the decoder 120 may determine whether the iteration count of a decoding operation has reached a threshold count. When the iteration count has not reached the threshold count, the process may proceed to the step S150.

At the step S150, the decoder 120 may perform the decoding operation for the codeword, and may increase the iteration count. Then, the process may proceed to the step S110.

At the step S110, the syndrome check unit 110 may perform the syndrome check operation for a codeword acquired as the decoding operation is performed. That is, the decoder 120 may iterate the decoding operation until the syndrome check operation is passed for a codeword acquired as the decoding operation is performed or the iteration count reaches the threshold count.

At the step S140, when the iteration count has reached the threshold count, the process may proceed to step S200.

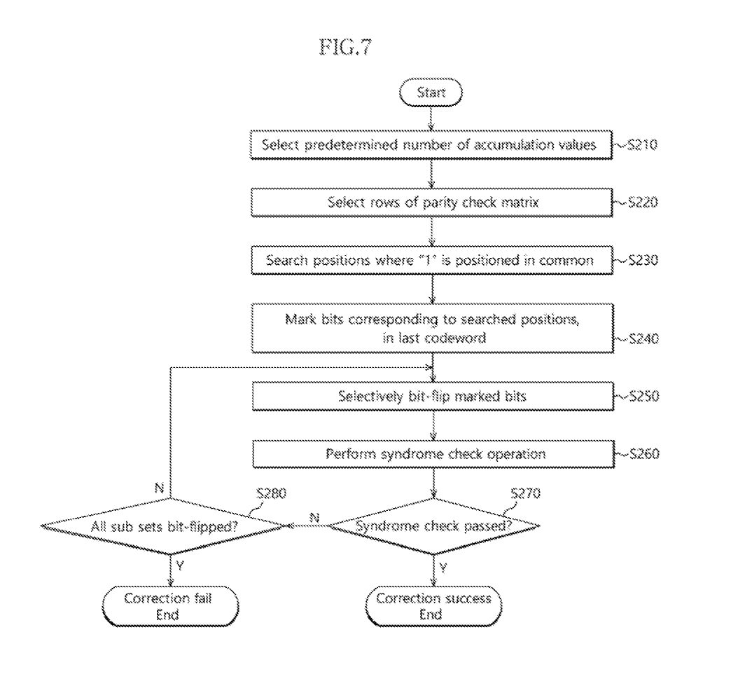

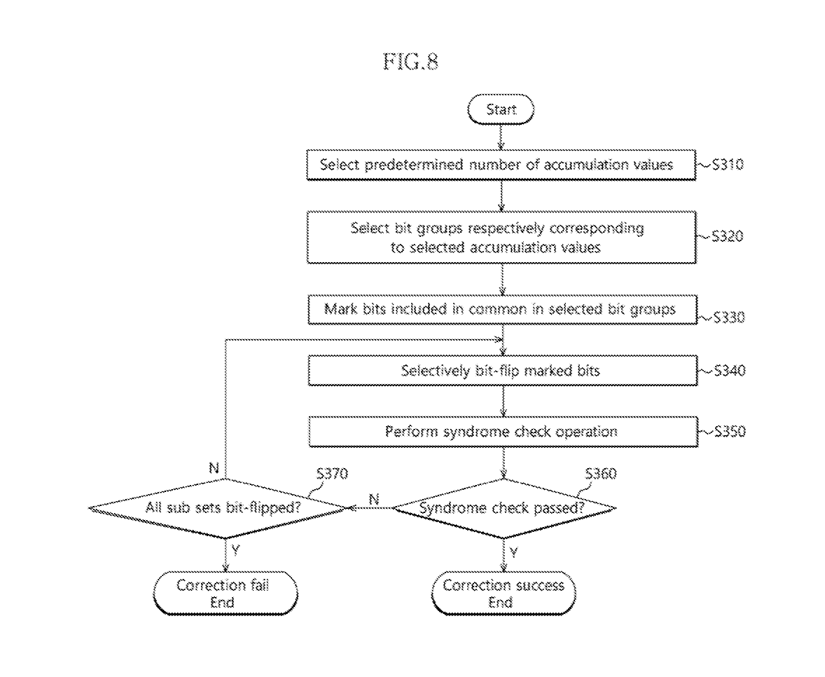

At the step S200, the error correction circuit 100 may perform a second error correction operation for a last codeword acquired through the decoding operation, based on the accumulation matrix. A method for performing the second error correction operation will be described below in detail with reference to FIGS. 7 and 8.

FIG. 7 is a flow chart illustrating a method for the error correction circuit 100 of FIG. 1 to perform the second error correction operation. The method shown in FIG. 7 may correspond to the method described above with reference to FIGS. 3 and 4.

At step S210, the bit flip unit 140 may select a predetermined number of accumulation values from the accumulation matrix. For example, the bit flip unit 140 may select a predetermined number of accumulation values by arranging the accumulation values of the accumulation matrix in a descending order. According to an embodiment, the bit flip unit 140 may select a predetermined number of accumulation values by arranging partial accumulation values of the accumulation matrix in a descending order, and the respective partial accumulation values may be ones having corresponding syndrome values in a last syndrome matrix corresponding to the last codeword that do not satisfy a syndrome check.

At step S220, the bit flip unit 140 may select one or more rows corresponding to the selected accumulation values among the rows of the parity check matrix.

At step S230, the bit flip unit 140 may search one or more positions where “1” is positioned in common in the selected rows.

At step S240, the bit flip unit 140 may mark or select one or more bits corresponding to the searched positions in the last codeword.

At step S250, the bit flip unit 140 may selectively bit-flip the marked bits in the last codeword. The bit flip unit 140 may bit-flip sub sets of the marked bits.

At step S260, the syndrome check unit 110 may perform the syndrome check operation for a bit-flipped codeword.

At step S270, the syndrome check unit 110 may determine whether the bit-flipped codeword has passed the syndrome check operation, based on a syndrome matrix corresponding to the bit-flipped codeword. When the syndrome matrix is “0,” the syndrome check unit 110 may determine that the bit-flipped codeword has passed the syndrome check operation, and the process may be ended as a correction success. When the syndrome matrix is not “0,” the syndrome check unit 110 may determine that the bit-flipped codeword has not passed the syndrome check operation, and the process may proceed to step S280.

At step S280, the bit flip unit 140 may determine whether all the sub sets of the marked bits are bit-flipped. When all the sub sets are bit-flipped, the process may be ended as a correction fail. When all the sub sets are not bit-flipped, the process may proceed to the step S250.

Summarizing these, the bit flip unit 140 may iterate the bit flip operation until the syndrome check operation is passed for the bit-flipped codeword or all the sub sets of the marked bits are bit-flipped.

FIG. 8 is a flow chart illustrating a method for the error correction circuit 100 of FIG. 1 to perform the second error correction operation. The method shown in FIG. 8 may correspond to the method described above with reference to FIG. 5.

In the process shown in FIG. 8, steps S310 and S340 to S370 may be substantially similar to the steps S210 and S250 to S280 of FIG. 7, respectively. Therefore, main differences from the process of FIG. 7 will be described below.

At step S320, the bit flip unit 140 may select bit groups respectively corresponding to selected accumulation values among the bit groups of the last codeword. The bit groups of the last codeword may respectively correspond to the syndrome values of the last syndrome matrix corresponding to the last codeword.

At step S330, the bit flip unit 140 may mark one or more bits which are included in common in all the selected bit groups.

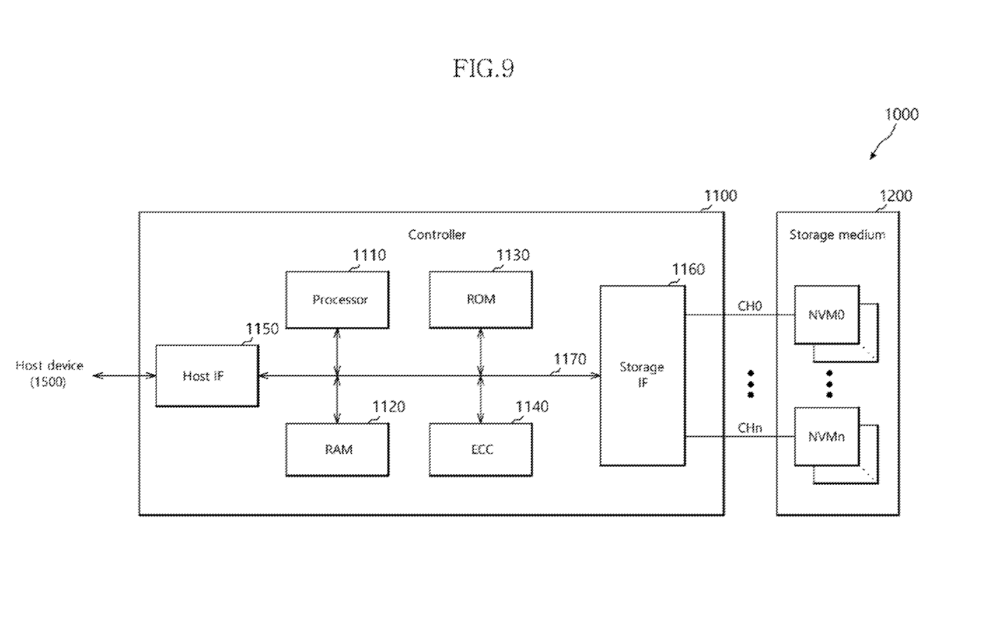

FIG. 9 is a block diagram illustrating a data storage device 1000 to which the error correction circuit 100 in accordance with the embodiment is applied.

The data storage device 1000 may be configured to store data provided from an external device, in response to a write request from the external device. Also, the data storage device 1000 may be configured to provide stored data to the external device, in response to a read request from the external device.

The data storage device 1000 may be configured by one of a Personal Computer Memory Card International Association (PCMCIA) card, a Compact Flash (CF) card, a smart media card, a memory stick, various multimedia cards (MMC, eMMC, RS-MMC, and MMC-Micro), various secure digital cards (SD, Mini-SD, and Micro-SD), a Universal Flash Storage (UFS), a Solid State Drive (SSD) and the like.

The data storage device 1000 may include a controller 1100 and a storage medium 1200.

The controller 1100 may control data exchange between a host device 1500 and the storage medium 1200. The controller 1100 may include a processor 1110, a random access memory (RAM) 1120, a read only memory (ROM) 1130, an error correction code (ECC) unit 1140, a host interface 1150, and a storage medium interface 1160.

The processor 1110 may control general operations of the controller 1100. The processor 1110 may store data in the storage medium 1200 and read stored data from the storage medium 1200, according to data processing requests from the host device 1500. To efficiently manage the storage medium 1200, the processor 1110 may control internal operations of the data storage device 1000 such as a merge operation, a wear leveling operation, and so forth.

The RAM 1120 may store programs and program data used by the processor 1110. The RAM 1120 may temporarily store data received from the host interface 1150 before transferring it to the storage medium 1200, and may temporarily store data received from the storage medium 1200 before transferring it to the host device 1500.

The ROM 1130 may store program codes read by the processor 1110. The program codes may include commands to be processed by the processor 1110, so that the processor 1110 can control the internal units of the controller 1100.

The ECC unit 1140 may encode data stored in the storage medium 1200, and may decode data read from the storage medium 1200. The ECC unit 1140 may detect and correct an error which occurred in the data according to an ECC algorithm.

The ECC unit 1140 may include the error correction circuit 100 of FIG. 1. The ECC unit 1140 may perform a first error correction operation by iterating a decoding operation to a threshold count for a codeword read from the storage medium 1200 according to a result of a syndrome check operation. The ECC unit 1140 may accumulate syndrome matrixes calculated as the decoding operation is iterated in the first error correction operation, to an accumulation matrix. The ECC unit 1140 may perform a second error correction operation by selectively bit-flipping bits having a high probability to be error bits from a last codeword based on the accumulation matrix, when the iteration count of the first error correction operation reaches a threshold count M.

The host interface 1150 may exchange data processing requests, data, etc. with the host device 1500.

The storage medium interface 1160 may transmit control signals and data to the storage medium 1200. The storage medium Interface 1160 may receive data from the storage medium 1200. The storage medium interface 1160 may be coupled with the storage medium 1200 through a plurality of channels CH0 to CHn.

The storage medium 1200 may include a plurality of nonvolatile memory devices NVM0 to NVMn. Each of the plurality of nonvolatile memory devices NVM0 to NVMn may perform a write operation and a read operation according to control of the controller 1100.

The nonvolatile memory device may include one of a flash memory, such as NAND flash or NOR flash, a Ferroelectrics Random Access Memory (FeRAM), a Phase-Change Random Access Memory (PCRAM), a Magnetoresistive Random Access Memory (MRAM), a Resistive Random Access Memory (ReRAM), and the like.

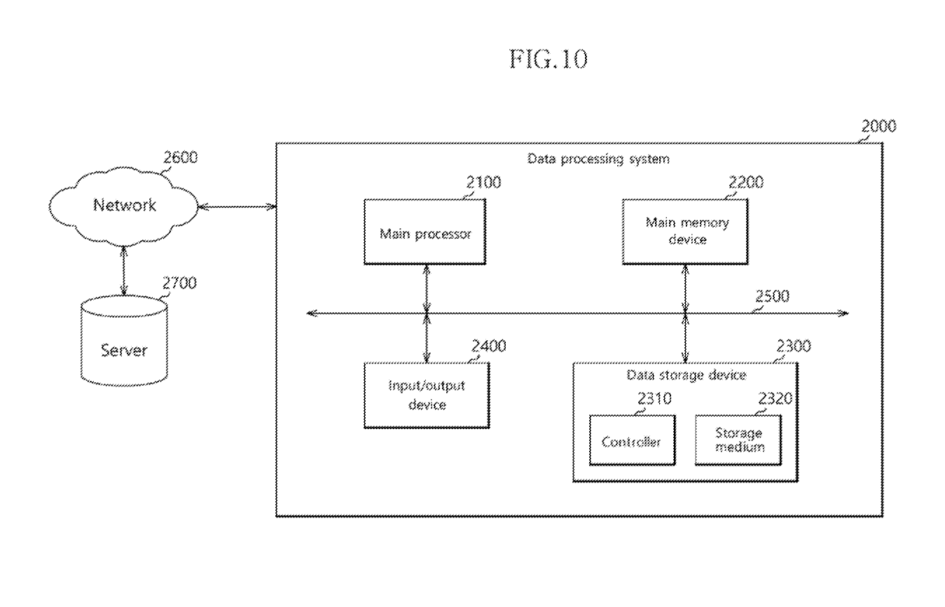

FIG. 10 is a block diagram illustrating a data processing system 2000 in which the data storage device 1000 of FIG. 9 is applied as a data storage device 2300. The data storage device 1000 of FIG. 9 may be realized as the data storage device 2300 in FIG. 10.

The data processing system 2000 may include a computer, a laptop, a netbook, a smart phone, a digital TV, a digital camera, a navigator, etc. The data processing system 2000 may include a main processor 2100, a main memory device 2200, a data storage device 2300, and an input/output device 2400. The internal units of the data processing system 2000 may exchange data, control signals, etc. through a system bus 2500.

The main processor 2100 may control general operations of the data processing system 2000. For example, the main processor 2100 may be a central processing unit such as a microprocessor. The main processor 2100 may execute the software of an operation system, an application, a device driver, and so forth, on the main memory device 2200.

The main memory device 2200 may store programs and program data used by the main processor 2100. The main memory device 2200 may temporarily store data transmitted to the data storage device 2300 and the input/output device 2400.

The data storage device 2300 may include a controller 2310 and a storage medium 2320. The data storage device 2300 may be configured and operate in a manner substantially similar to the data storage device 1000 shown in FIG. 9.

The input/output device 2400 may include a keyboard, a scanner, a touch screen, a screen monitor, a printer, a mouse, or the like, capable of exchanging data with a user, such as receiving a command for controlling the data processing system 2000 from the user or providing a processed result to the user.

According to an embodiment, the data processing system 2000 may communicate with at least one server 2700 through a network 2600 such as a local area network (LAN), a wide area network (WAN), a wireless network, and so on. The data processing system 2000 may include a network interface (not shown) to access the network 2600.

While various embodiments have been described above, it will be understood to those skilled in the art that the embodiments described are examples only. Accordingly, the data storage device and the operating method thereof described herein should not be limited based on the described embodiments. Many other embodiments and or variations thereof may be envisaged by those skilled in the relevant art without departing from the spirit and or scope of the present invention as defined in the following claims.

What is claimed is:

1. An error correction method comprising:
performing a first error correction operation, the first error correction operation including performing a syndrome check operation by calculating a syndrome matrix corresponding to a codeword based on a parity check matrix, performing a decoding operation for the codeword according to a result of the syndrome check operation, and iterating the decoding operation until the syndrome check operation is passed for a codeword acquired as the decoding operation is performed or an iteration count of the decoding operation reaches a threshold count;
accumulating syndrome matrixes, which are calculated as the decoding operation is iterated, to an accumulation matrix; and
performing a second error correction operation for a last codeword acquired through the iterating of the decoding operation for the codeword, based on the accumulation matrix, when the iteration count reaches the threshold count.

2. The error correction method according to claim 1, wherein the performing of the second error correction operation comprises:
selecting a predetermined number of accumulation values in the accumulation matrix;
selecting one or more bits in the last codeword, based on the selected accumulation values;
selectively bit-flipping the selected bits; and
performing the syndrome check operation for a bit-flipped codeword.

3. The error correction method according to claim 2, wherein the selecting of the accumulation values comprises:
selecting the predetermined number of accumulation values by arranging accumulation values of the accumulation matrix in a descending order.

4. The error correction method according to claim 2,
wherein the selecting of the accumulation values comprises:
selecting the predetermined number of accumulation values by arranging partial accumulation values of the accumulation matrix in descending order, and
wherein the respective partial accumulation values have corresponding syndrome values in a last syndrome matrix corresponding to the last codeword that do not satisfy a syndrome check.

5. The error correction method according to claim 2, wherein the selecting of the bits comprises:
selecting one or more rows corresponding to the selected accumulation values among rows of the parity check matrix;
searching one or more positions for a predetermined value which is positioned in common in the selected rows; and
selecting the one or more bits corresponding to the searched positions, in the last codeword.

6. The error correction method according to claim 2, wherein the selecting of the bits comprises:
selecting bit groups respectively corresponding to the selected accumulation values among bit groups of the last codeword; and
selecting the one or more bits which are included in common in all of the selected bit groups.

7. The error correction method according to claim 2, wherein the performing of the second error correction operation further comprises:
iterating bit-flipping for sub sets of the selected bits until the syndrome check operation is passed.

8. An error correction method comprising:
calculating syndrome values for respective bit groups of a codeword based on a parity check matrix, while a decoding operation is iterated to a threshold count;
counting dissatisfaction counts as counts in which the respective bit groups have not satisfied a syndrome check, based on the syndrome values;
selecting a predetermined number of bit groups among bit groups of a last codeword acquired through the decoding operation, based on the dissatisfaction counts of the bit groups;
selecting one or more bits which are included in common in all of the selected bit groups;
selectively bit-flipping the selected bits; and
performing a syndrome check operation for a bit-flipped codeword.

9. The error correction method according to claim 8, wherein the selecting of the bit groups comprises:
selecting the predetermined number of bit groups by arranging the dissatisfaction counts in a descending order.

10. The error correction method according to claim 8,
is wherein the selecting of the bit groups comprises:
selecting the predetermined number of bit groups by arranging partial dissatisfaction counts among the dissatisfaction counts in a descending order, and
wherein the respective partial dissatisfaction counts have corresponding syndrome values in a last syndrome matrix corresponding to the last codeword that do not satisfy a syndrome check.

11. The error correction method according to claim 8, further comprising:
iterating bit-flipping for sub sets of the selected bits until the syndrome check operation is passed.

12. The error correction method according to claim 8, further comprising:
performing the decoding operation for the bit-flipped codeword according to a result of the syndrome check operation for the bit-flipped codeword.

13. An error correction method comprising:
acquiring codewords while a decoding operation is iterated to a threshold count according to a result of a syndrome check operation, the syndrome check operation including calculating syndrome matrixes respectively corresponding to the codewords;
accumulating the syndrome matrixes to an accumulation matrix; and
performing a bit-flip operation for a last codeword among the codewords, based on the accumulation matrix.

14. The error correction method according to claim 13, wherein the performing of the bit-flip operation comprises:
selecting a predetermined number of accumulation values in the accumulation matrix;
selecting one or more bits in the last codeword based on the selected accumulation values;
selectively bit-flipping the selected bits; and
performing the syndrome check operation for a bit-flipped codeword.

15. The error correction method according to claim 14, wherein the selecting of the accumulation values comprises:
selecting the predetermined number of accumulation values by arranging accumulation values of the accumulation matrix in a descending order.

16. The error correction method according to claim 14,
wherein the selecting of the accumulation values comprises:
selecting the predetermined number of accumulation values by arranging partial accumulation values of the accumulation matrix in a descending order, and
wherein the respective partial accumulation values have corresponding syndrome values in a last syndrome matrix corresponding to the last codeword that do not satisfy a syndrome check.

17. The error correction method according to claim 14, wherein the selecting of the bits comprises:
selecting bit groups respectively corresponding to the selected accumulation values among bit groups of the last codeword, the bit groups of the last codeword respectively corresponding to the syndrome values of the last syndrome matrix corresponding to the last codeword; and
selecting the one or more bits which are included in common in all of the selected bit groups.

18. The error correction method according to claim 14, wherein the performing of the bit-flip operation further comprises:
iterating bit-flipping for sub sets of the selected bits until the syndrome check operation is passed.
